(19) United States
(12) Patent Application Publication
(10) Pub. No.: US 2013/0292812 A1
(43) Pub. Date: Nov. 7, 2013

(54) LEAD FRAME FOR SEMICONDUCTOR DEVICE AND SEMICONDUCTOR DEVICE PACKAGE USING THE LEAD FRAME

(71) Applicant: SAMSUNG ELECTRONICS CO., LTD., SUWON-SI (KR)

(72) Inventors: Young-chun SEO, Yongin-si (KR); Jae-kwan HAN, Hwaseong-si (KR); Kyu-chae CHO, Pohang-si (KR)

(73) Assignee: SAMSUNG ELECTRONICS CO., LTD., SUWON-SI (KR)

(21) Appl. No.: 13/730,643

(22) Filed: Dec. 28, 2012

(30) Foreign Application Priority Data
May 7, 2012 (KR) 10-2012-0048315

(51) Int. Cl. H01L 23/495

(52) U.S. Cl. CPC H01L 23/49541; H01L 23/49575
USPC 257/676

(57) ABSTRACT

A lead frame for a semiconductor device and a semiconductor device package using the lead frame. The lead frame includes a package body having an internal space configured to mount a semiconductor device, and a lead unit disposed so as to apply voltages to the semiconductor device. The lead unit includes internal leads embedded in the package body and having an area in which the semiconductor device is to be mounted, and external leads each being connected to the internal leads, respectively . Each external lead protrudes from the package body and each has a contact portion that contacts a printed circuit board (PCB). The lead frame also includes and a support structure disposed on external sides of the package body and supporting the external leads.

### CROSS-REFERENCE TO RELATED APPLICATIONS

This application claims the benefit of priority to Korean Patent Application No. 10-2012-0048315, filed on May 7, 2012, in the Korean Intellectual Property Office, the disclosure of which is incorporated herein in its entirety by reference.

### TECHNICAL FIELD

The present inventive concept relates to a lead frame for a semiconductor device on which the semiconductor device is to be mounted, and a semiconductor device package using the lead frame.

### BACKGROUND

Semiconductor device packages are fabricated to mount semiconductor chips in a semiconductor device package, to connect the semiconductor chips and leads to each other and to attach the semiconductor chips to a printed circuit board (PCB). Semiconductor device packages serve to protect semiconductor chips from an external environment, electrically connect terminals to the PCB, and transfer heat generated in the semiconductor chips to the outside.

A lead frame component of a semiconductor device package serves to mount the semiconductor device and includes leads which connect to an external voltage source so as to apply voltages to positive and negative electrodes of the semiconductor device. Various designs have been suggested for such lead frame components. When designing lead frames the ease of mounting a semiconductor device package on the PCB, and the size of the semiconductor device package may be important considerations. In particular, design of a structure that takes into consideration maintaining the reliability of an electrical junction portion throughout the manufacturing process, including while the semiconductor device package is undergoing sorting and packaging operations, and until the semiconductor device package manufacturing is completed is needed.

### SUMMARY

According to an aspect of the inventive concept, provided is a lead frame. The lead frame includes a package body having an internal space configured to mount a semiconductor device. A lead unit is disposed so as to apply voltages to the semiconductor device and includes internal leads embedded in the package body and has an area in which the semiconductor device is to be mounted. Each external lead is connected to the internal leads, respectively, each protruding from the package body and each having a contact portion that contacts a printed circuit board (PCB). A support structure is disposed on external sides of the package body and supporting the external leads.

The lead unit may include a first lead unit and a second lead unit, and the first lead unit may include a first internal lead and a first external lead. The second lead unit may include a second internal lead and a second external lead, and the first external lead and the second external lead may be bent along the external sides of the package body.

The external sides of the package body may include: a left side; a right side that faces the left side; a front side that connects the left side and the right side; a rear side that faces the front side; and a bottom side that connects the left side and the right side and connects the front side and the rear side.

The first external lead may protrude from the left side, may be bent, may reach an end of the left side in which the left side joins the bottom side, and may be bent from the end of the left side to extend away from the left side. The second external lead may protrude from the right side, may be bent, may reach an end of the right side in which the right side joins the bottom side, and may be bent from the end of the right side to extend away from the right side.

The support structure may include: a first stopper that protrudes from the left side and is disposed between a surface on which the rear side extends, and the first external lead; and a second stopper that protrudes from the right side and is disposed between the surface on which the rear side extends, and the second external lead.

The first external lead may protrude from the left side, may be bent, and may extend to the front side, and the second external lead may protrude from the right side, may be bent, and may extend to the front side.

The support structure may include: a first stopper that protrudes from the front side and is disposed between a surface on which the bottom side extends, and the first external lead; and a second stopper that protrudes from the front side and is disposed between the surface on which the bottom side extends, and the second external lead.

The first external lead may protrude from the left side, may be bent, and may extend to the bottom side, and the second external lead may protrude from the right side, may be bent, and may extend to the bottom side.

The support structure may include: a first stopper that protrudes from the bottom side and is disposed between a surface on which the rear side extends, and the first external lead; and a second stopper that protrudes from the bottom side and is disposed between the surface on which the rear side extends, and the second external lead.

The lead unit may include one selected from the group consisting of copper (Cu), aluminum (Al), silver (Ag), and gold (Au).

The support structure may be disposed parallel to the external leads by a predetermined distance.

The support structure may not be more protruding than the contact portion of each of the external leads.

The package body may include a thermoplastic resin or a thermosetting resin.

According to another aspect of the inventive concept, there is provided a semiconductor device package including: a semiconductor device; a package body having an internal space in which the semiconductor device is capable of being mounted. The semiconductor package may also include a lead unit disposed so as to apply voltages to the semiconductor device and include internal leads embedded in the package body and have an area in which the semiconductor device is to be mounted. The external leads may each be connected to the internal leads, respectively, each protruding from the package body and each having a contact portion that contacts a printed circuit board (PCB). A support structure may be disposed on external sides of the package body so as to support the external leads.

The external sides of the package body may include: a left side; a right side that faces the left side; a front side that connects the left side and the right side; a rear side that faces the front side; and a bottom side that connects the left side and the right side and connects the front side and the rear side, and the lead unit may include a first lead unit and a second lead unit, and the first lead unit may include a first internal lead and a first external lead, the second lead unit may include a second internal lead and a second external lead, and the first external lead and the second external lead may be bent along the external sides of the package body, and the first external lead may protrude from the left side, may be bent, may reach an end of the left side in which the left side joins the bottom side, and may be bent from the end of the left side to extend away from the left side, and the second external lead may protrude from the right side, may be bent, may reach an end of the right side in which the right side joins the bottom side, and may be bent from the end of the right side to extend away from the right side.

The support structure may include: a first stopper that protrudes from the front side and is disposed between a surface on which the bottom side extends, and the first external lead;

and a second stopper that protrudes from the front side and is disposed between the surface on which the bottom side extends, and the second external lead.

The semiconductor device may include a light emitting device.

The semiconductor device package may further include: a fluorescent body disposed on at least one surface of the light emitting device so as to control color of light emitted from the light emitting device; and an encapsulation member that encapsulates the light emitting device and the fluorescent body so as to protect the light emitting device.

One of the first internal lead and the second internal lead may contact a P-electrode of the light emitting device, and the other one of the first internal lead may contact an N-electrode of the light emitting device.

The external leads may include one selected from the group consisting of copper (Cu), aluminum (Al), silver (Ag), and gold (Au).

The support structure may be disposed at one side of each of the external leads.

The support structure may not be more prominent than the contact portion of each of the external leads.

The package body may include a thermoplastic resin or a thermosetting resin.

According to another aspect, provided is a lead frame comprising a package body having an internal space configured to mount a semiconductor device, and a lead unit configured to apply voltages to the semiconductor device. The lead unit comprises internal leads embedded in the package body and has an area in which the semiconductor device is to be mounted, and external leads each being connected to the internal leads respectively, protruding from the package body, and having a contact portion that contacts a printed circuit board (PCB). The lead frame also comprises a support structure integrally disposed on external sides of the package body and comprising edge portions directly adjacent and in contact with a side portion of the external leads.

### BRIEF DESCRIPTION OF THE DRAWINGS

Exemplary embodiments of the inventive concept will be more clearly understood from the following detailed description taken in conjunction with the accompanying drawings in which:

FIG. 1A is a perspective view of a lead frame according to an embodiment of the inventive concept;

FIG. 1B is a cross-sectional view of the lead frame illustrated in FIG. 1A, taken along a line A-A′;

FIG. 2 is a perspective view of a lead frame according to another embodiment of the inventive concept;

FIG. 3A is a partial perspective view of a lead frame according to another embodiment of the inventive concept;

FIG. 3B is a cross-sectional view of the lead frame illustrated in FIG. 3A, taken along a line A-A′; and

FIGS. 4 through 6 illustrate semiconductor device packages having various shapes of semiconductor devices, according to other embodiments of the inventive concept.

### DETAILED DESCRIPTION OF THE EMBODIMENTS

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

As used herein, the term “and/or” includes any and all combinations of one or more of the associated listed items.

Hereinafter, the inventive concept will be described in detail by explaining embodiments with reference to the attached drawings. Like reference numerals in the drawings denote like elements. Sizes or thicknesses of elements may be exaggerated for clarity of explanation.

In the present application, a direction and position relationship that will be mentioned when a lead frame or a structure of a semiconductor device package is described, is based on the drawings, and when the direction and position relationship is not clearly mentioned, the related drawings will be referred to.

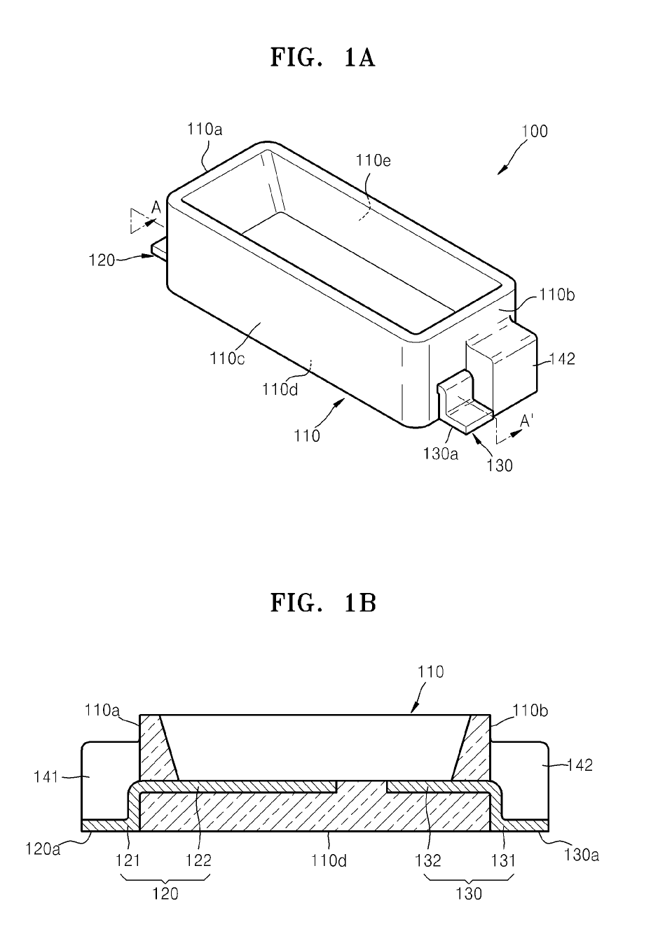

FIG. 1A is a perspective view of a lead frame 100 according to an embodiment of the inventive concept, and FIG. 1B is a cross-sectional view of the lead frame 100 illustrated in FIG. 1A, taken along a line A-A′.

Referring to FIGS. 1A and 1B, the lead frame 100 includes: a package body 110 having an internal space in which a semiconductor device (not shown) may be mounted and a lead unit disposed so as to apply voltages to the semiconductor device. The lead unit includes internal leads embedded in the package body 110 and has an area in which the semiconductor device is mounted. The lead unit further includes external leads each of which are connected to the internal leads, respectively. The external leads each protrude from the package body 110 and each have a contact portion that contacts a printed circuit board (PCB). The lead frame also includes a support structure disposed on external sides of the package body 110. The support structure serves to support the external leads.

The package body 110 is configured to secure and protect the semiconductor device to be mounted in the semiconductor device package. In addition, the package body 110 secures and supports the lead unit for applying voltages to the semiconductor device.

The package body 110 may be formed of a material that electrically insulates and may be injection molded. For example, the package body 110 may be formed of a well-known thermoplastic resin, such as liquid crystal polymer, polyphthalamide (PPA) resin, polybutylene terephthalate (PBT), or the like.

The package body 110 may have various shapes, such as a hexahedral , cylindrical, multiple pillars, and the like, depending on the purpose and design of the semiconductor device, and aspects of the inventive concept are not limited thereto.

FIGS. 1A and 1B illustrate an exemplary shape of the package body 110. In detail, the external sides of the package body 110 include: a left side 110a; a right side 110b that faces the left side 110a; a front side 110c that connects the left side 110a and the right side 110b; a rear side 110e that faces the front side 110c; and a bottom side 110d that connects the left side 110a and the right side 110b and connects the front side 110c and the rear side 110e.

The lead unit includes a first lead unit 120 and a second lead unit 130 that are spaced apart from each other by a predetermined distance. The first lead unit 120 includes a first internal lead 122 and a first external lead 121, and the second lead unit 130 includes a second internal lead 132 and a second external lead 131. The first external lead 121 of the first lead unit 120 and the second external lead 131 of the second lead unit 130 may be bent along the external sides of the package body 110. The first internal lead 122 of the first lead unit 120 and the second internal lead 132 of the second lead unit 130 are connected to the semiconductor device inside the package body 110, and the first external lead 121 of the first lead unit 120 and the second external lead 131 of the second lead unit 130 protrude from the package body 110.

The lead unit serves to supply power to the semiconductor device and to dissipate heat generated in the semiconductor device. Thus, the first and second lead units 120 and 130 may be formed of material having high electrical conductivity and high thermal conductivity, for example, copper (Cu), aluminum (Al), silver (Ag), gold (Au), or material that is formed by plating Cu or Al with Ag or Au. In addition, the lead unit may have a single layer structure, or a multi-layered structure, and aspects of the inventive concept are not limited thereto.

The first external lead 121 and the second external lead 131 are mounted on the PCB, and power is supplied to the first external lead 121 and the second external lead 131. In this case, the first external lead 121 and the second external lead 131 may be bent or formed in various shapes so as to reduce the size of the semiconductor device package, and based on the position of the first external lead 121 and the second external lead 131 in the PCB, and the like. Thus, the external lead may be formed of a soft material that may be bent. The length, width, or the thickness of the external leads may vary according to the utilization of the semiconductor device.

Referring to FIGS. 1A and 1B, the first external lead 121 protrudes from the left side 110a of the package body 110, is bent, and reaches an end of the left side 110a of the package body 110 in which the left side 110a of the package body 110 joins the bottom side 110d of the package body 110. The first external lead 121 is then bent again from the end of the left side 110a so as to extend away from the left side 110a. The second external lead 131 protrudes from the right side 110b of the package body 110, is bent, and reaches an end of the right side 110b of the package body 110 in which the right side 110b of the package body 110 joins the bottom side 110d. The second external lead 131 is bent again a from the end of the right side 110b to extend away from the right side 110b of the package body.

In this case, a first contact portion 120a of the first external lead 121 and a second contact portion 130a of the second external lead 131 are disposed on a surface on which the bottom side 110d of the package body 110 extends, and thus the bottom side 110d of the package body 110 is mounted on the PCB. That is, the first contact portion 120a of the first external lead 121 and the second contact portion 130a of the second external lead 131 are electrically connected to the PCB, and voltages are supplied to the first contact portion 120a and the second contact portion 130a.

The support structure prevents the external leads from being deformed by an external shock. The support structure may be formed as one body with the package body 110. In addition, the support structure may have the shape of a stopper that protrudes from the package body 110.

Referring to FIGS. 1A and 1B, the support structure includes a first stopper 141 and a second stopper 142. The first stopper 141 prevents deformation of the first external lead 121, and the second stopper 142 prevents deformation of the second external lead 131. For example, if the semiconductor device package suffers an external impact during some stage of the mass production process, such as during a process checking operation, a transferring operation, a packaging operation, and the like, the support structure serves to prevent deformation of the external leads.

The first stopper 141 protrudes from the package body 110 and may be disposed between a surface on which the rear side 110e of the package body 110 extends, and the first external lead 121, or between a surface on which the front side 110c of the package body 110 extends, and the first external lead 121. Alternatively, the stopper may be disposed between the surface on which the rear side 110e of the package body 110 extends, and the first external lead 121 and between the surface on which the front side 110c of the package body 110 extends, and the first external lead 121. In addition, the second stopper 142 protrudes from the package body 110 and may be disposed between the surface on which the rear side 110e of the package body 110 extends, and the second external lead 131, or between the surface on which the front side 110c of the package body 110 extends, or between the surface on which the rear side 110e of the package body 110 extends, and the second external lead 131 and between the surface on which the front side 110c of the package body 110 extends.

The first and second stoppers 141 and 142 may be formed in consideration of a final shape of the external leads. The distance between the stopper and the external lead may be minimum in consideration of a process error. For example, a distance between the first stopper 141 and the first external lead 121 and/or a distance between the second stopper 142 and the second external lead 131 may be between about 0.1 mm and about 0.3 mm.

In addition, the first and second stoppers 141 and 142 may not protrude more than the first and second contact portions 121a and 131a of the first and second external leads 121 and 131 on which the external leads are mounted on the PCB. That is, the bottom face of the first stopper 141 may be in the same plane as or may be on a higher plane than the first contact portion 120a of the first external lead 121, and a bottom face of the second stopper 142 may be in the same plane as or may be on a higher plane than the second contact portion 130a of the second external lead 131.

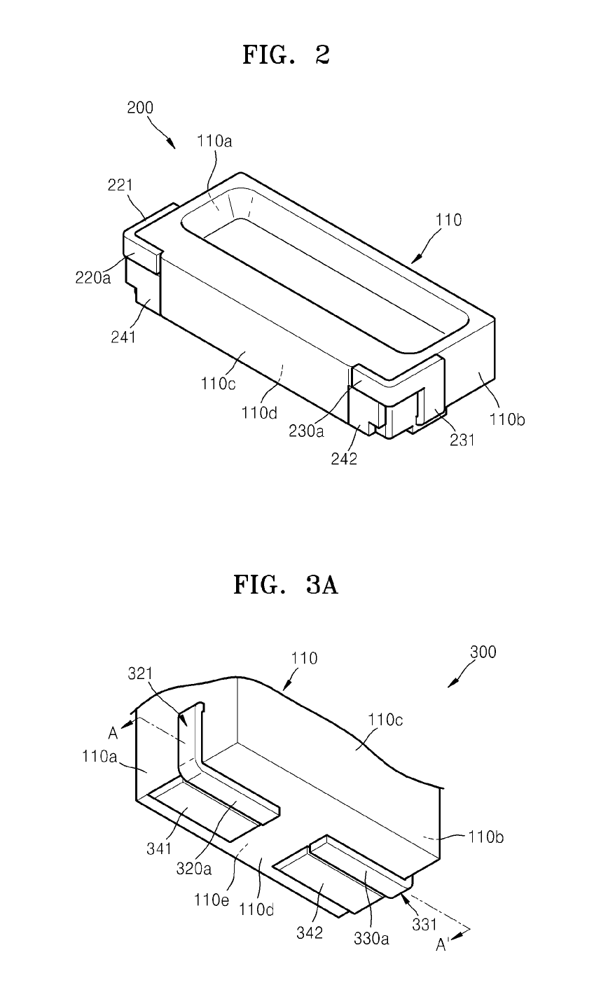

FIG. 2 is a perspective view of a lead frame 200 according to another embodiment of the inventive concept.

Referring to FIG. 2, a first external lead 221 protrudes from a left side 110a of a package body 110, is bent, and extends to a front side 110c of the package body 110. A second external lead 231 protrudes from a right side 110b of the package body 110, is bent, and extends to the front side 110c of the package body 110.

In more detail, the first external lead 221 protrudes from a lower part of the left side 110a of the package body 110. The external lead is bent, and extends to an upper part of the left side 110a along the left side 110a. The external lead is then bent at the upper part of the left side 110a, and reaches an end where the left side 110a of the package body 110 joins the front side 110c of the package body 110. The external lead is then bent at the end of the left side 110a and extends along the front side 110c of the package body 110.

In addition, the second external lead 231 protrudes from a lower part of the right side 110b of the package body 110, and is bent. The second external lead extends to an upper part of the right side 110b along the right side 110b and then is bent at the upper part of the right side 110b. The second external lead then reaches an end where the right side 110b of the package body 110 joins the front side 110c of the package body 110. The second external lead is bent at the end of the right side 110b and extends along the front side 110c of the package body 110.

The structure of the second external lead 231 may be formed when external terminals disposed at the front side 110c of the lead frame 200 are electrically connected to the PCB.

Thus, a first contact portion 220a of the first external lead 221 and a second contact portion 230a of the second external lead 231 that contact the PCB, are disposed at the front side 110c of the lead frame 200.

In the structure of the second external lead 231, a first stopper 241 protrudes from the front side 110c of the package body 110 so as to support the first external lead 221 and is disposed between a surface on which a bottom side 110d of the package body 110 extends and the first external lead 221. Likewise, a second stopper 242 protrudes from the front side 110c of the package body 110 so as to support the second external lead 231 and is disposed between the surface on which the bottom side 110d of the package body 110 extends, and the second external lead 231.

The distance between the external leads and the first and second stoppers 241 and 242 may be minimum in consideration of a process error. In addition, the first stopper 241 and the second stopper 242 each do not protrude more than the first contact portion 220a of the first external lead 221 and the second contact portion 230a of the second external lead 231, respectively. Front faces of the first stopper 241 and the second stopper 242 may be the same planes as the first contact portion 220a of the first external lead 221 and the second contact portion 230a of the second external lead 231, respectively.

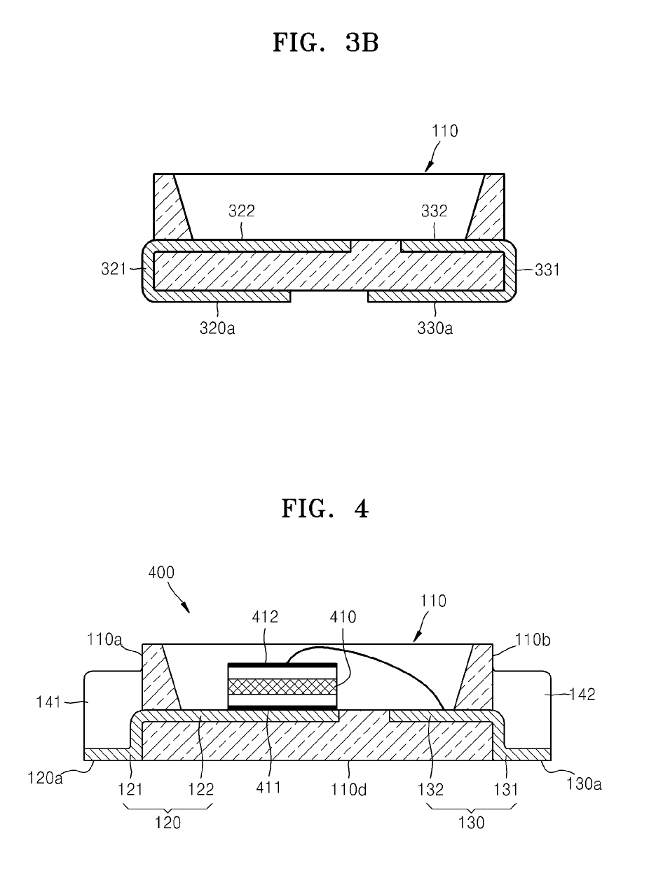

FIG. 3A is a partial perspective view of a lead frame 300 according to another embodiment of the inventive concept, and FIG. 3B is a cross-sectional view of the lead frame 300 illustrated in FIG. 3A, taken along a line A-A′.

Referring to FIGS. 3A and 3B, a first external lead 321 protrudes from a left side 110a of a package body 110, is bent and extends to a bottom side 110d of the package body 110. A second external lead 331 protrudes from a right side 110b of the package body 110, is bent and extends to the bottom side 110d of the package body 110.

In more detail, the first external lead 321 protrudes from the left side 110a of the package body 110, is bent toward the bottom side 110d of the package body 110, extends to an end where the left side 110a joins the bottom side 110d, is bent at the end of the left side 110a and extends along the bottom side 110d of the package body 110.

In addition, the second external lead 331 protrudes from the right side 110b of the package body 110, is bent toward the bottom side 110d of the package body 110, extends to an end where the right side 110b joins the bottom side 110d, is bent at the end of the right side 110b and extends along the bottom side 110d of the package body 110.

The structure of the second external lead 331 may be formed when the bottom side 110d of the lead frame 300 contacts the PCB. In the structure of the second external lead 331, a first stopper 341 may be disposed between a surface on which the front side 110c of the package body 110 extends, and the first external lead 321, or between a surface on which a rear side 110e of the package body 110 extends, and the first external lead 321, or between the surface on which the front side 110c of the package body 110 extends, and the first external lead 321 and between the surface on which the rear side 110e of the package body 110 extends, and the first external lead 321, so as to protect and support the first external lead 321. Likewise, a second stopper 342 may be disposed between a surface on which the front side 110c of the package body 110 extends, and the second external lead 331, or between a surface on which the rear side 110e of the package body 110 extends, and the second external lead 331, or between the surface on which the front side 110c of the package body 110 extends, and the second external lead 331 and between the surface on which the rear side 110e of the package body 110 extends, and the second external lead 331, so as to protect and support the second external lead 331.

In addition, the first stopper 341 and the second stopper 342 may not protrude more than a first contact portion 320a of the first external lead 321 and a second contact portion 330a of the second external lead 331, respectively, and bottom faces of the first stopper 341 and the second stopper 342 may be in the same planes as the first contact portion 320a of the first external lead 321 and the second contact portion 330a of the second external lead 331, respectively.

The height of the first contact portion 320a of the first external lead 321 from the bottom side 110d of the package body 110 and the height of the second contact portion 330a of the second external lead 331 from the bottom side 110d of the package body 110 may be similar to each other.

The lead frame may be manufactured by compression molding and injection molding so as to fabricate semiconductor device packages in a mass production manner. However, in the present specification, a method of fabricating the lead frame is not limited.

FIGS. 4 through 6 show semiconductor device packages 400, 500, and 600 according to other embodiments of the inventive concept.

Referring to FIG. 4, the semiconductor device package 400 includes a lead frame 100 (see FIG. 1) and a semiconductor device mounted on the lead frame. In FIG. 4, a light emitting diode (LED) chip 410 that is a semiconductor device, is mounted in the lead frame 100. The LED chip 410 has a P- or N-junction structure for various compound semiconductors as a light-emitting structure. The LED chip 410 is configured to emit blue light, green light, red light, or the like depending on the material(s) used in forming the LED chip 410. In addition, the LED chip 410 may be coated with a fluorescent layer so as to emit light of various colors. In addition, the semiconductor device package 400 may include an encapsulation member that protects the LED chip 410 and enables light to be transmitted through the LED chip 410 so as to emit light to the outside. The encapsulation member may be formed of silicon or heat-resistant epoxy, for example.

In FIG. 4, the LED chip 410 is mounted on the lead frame 100 using die bonding. A first electrode 411 of the LED chip 410 is connected to a first internal lead 122 of the lead frame 100, and a second electrode 412 of the LED chip 410 is connected to a second internal lead 132 of the lead frame 100 using wire bonding. The first electrode 411 and the second electrode 412 of the LED chip 410 may each be a P-electrode or an N-electrode.

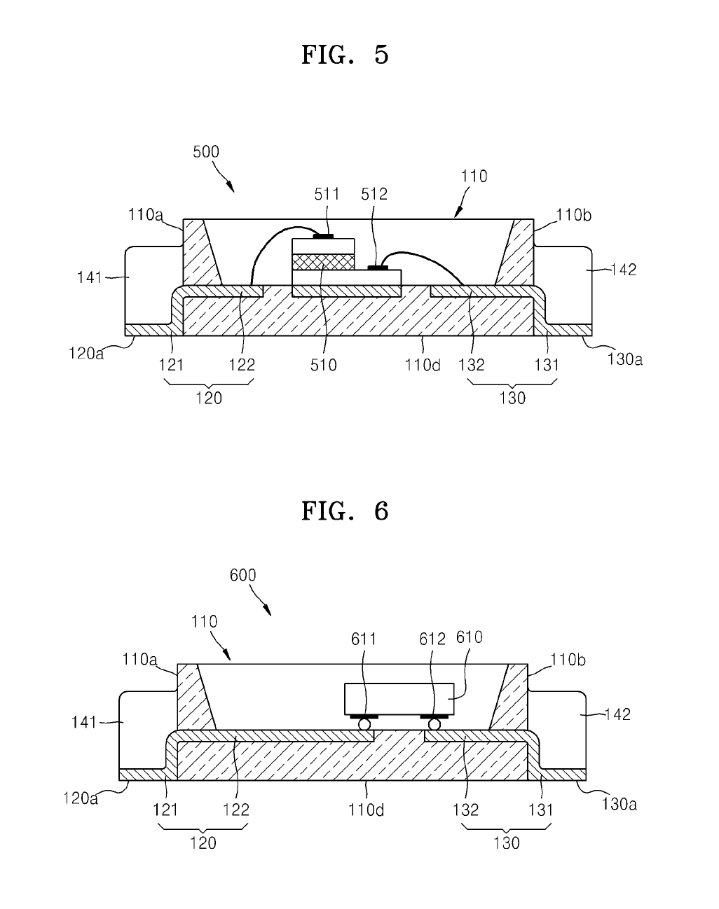

In FIG. 5, an LED chip 510 is mounted on the lead frame 100 using die bonding. A first electrode 511 and a second electrode 512 of the LED chip 510 are each connected to a first internal lead 122 and a second internal lead 132 of the lead frame 100, respectively, using wire bonding.

In FIG. 6, a first electrode 611 and a second electrode 612 of an LED chip 610 are each connected to a first internal lead 122 and a second internal lead 132 of a lead frame 100, respectively, using flip chip bonding.

Although the semiconductor device package 400 illustrated in FIG. 4 shows a shape of the lead frame 100 on which the LED chip 410 is mounted, this is just an example. Aspects of the inventive concept are not limited thereto, and other semiconductor devices may be used, and one lead frame selected from the above-described lead frames 100, 200, and 300, or other types of lead frames may be used.

As described above, in a semiconductor device package using the above-described lead frame according to the one or more embodiments of the inventive concept, stoppers are formed on a package body so that deformation of external leads by an external force can be prevented. Thus, process yield of semiconductor device packages can be improved and production costs can be reduced. In addition, when the semiconductor device package is mounted on a PCB, defects that may occur when the semiconductor package is not properly positioned, can be reduced.

While the inventive concept has been particularly shown and described with reference to exemplary embodiments thereof, it will be understood that various changes in form and details may be made therein without departing from the spirit and scope of the following claims.

What is claimed is:

1. A lead frame comprising:
a package body having an internal space configured to mount a semiconductor device;
a lead unit disposed so as to apply voltages to the semiconductor device and comprising internal leads embedded in the package body and having an area in which the semiconductor device is to be mounted, and external leads each being connected to the internal leads, respectively, each protruding from the package body and each having a contact portion that contacts a printed circuit board (PCB); and
a support structure disposed on external sides of the package body and supporting the external leads.

2. The lead frame of claim 1, wherein the lead unit comprises a first lead unit and a second lead unit, and
the first lead unit comprises a first internal lead and a first external lead,
the second lead unit comprises a second internal lead and a second external lead, and
the first external lead and the second external lead are bent along the external sides of the package body.

3. The lead frame of claim 2, wherein the external sides of the package body comprise:
a left side;
a right side that faces the left side;
a front side that connects the left side and the right side;
a rear side that faces the front side; and
a bottom side that connects the left side and the right side and connects the front side and the rear side.

4. The lead frame of claim 3, wherein the first external lead protrudes from the left side, is bent, reaches an end of the left side in which the left side joins the bottom side, and is bent from the end of the left side to extend away from the left side, and
the second external lead protrudes from the right side, is bent, reaches an end of the right side in which the right side joins the bottom side, and is bent from the end of the right side to extend away from the right side.

5. The lead frame of claim 4, wherein the support structure comprises:
a first stopper that protrudes from the left side and is disposed between a surface on which the rear side extends, and the first external lead; and
a second stopper that protrudes from the right side and is disposed between the surface on which the rear side extends, and the second external lead.

6. The lead frame of claim 3, wherein the first external lead protrudes from the left side, is bent, and extends to the front side, and
the second external lead protrudes from the right side, is bent, and extends to the front side.

7. The lead frame of claim 4, wherein the support structure comprises:
a first stopper that protrudes from the front side and is disposed between a surface on which the bottom side extends, and the first external lead; and
a second stopper that protrudes from the front side and is disposed between the surface on which the bottom side extends, and the second external lead.

8. The lead frame of claim 3, wherein the first external lead protrudes from the left side, is bent, and extends to the bottom side, and
the second external lead protrudes from the right side, is bent, and extends to the bottom side.

9. The lead frame of claim 4, wherein the support structure comprises:
a first stopper that protrudes from the bottom side and is disposed between a surface on which the rear side extends, and the first external lead; and
a second stopper that protrudes from the bottom side and is disposed between the surface on which the rear side extends, and the second external lead.

10. The lead frame of claim 1, wherein the support structure is not more protruding than the contact portion of each of the external leads.

11. The lead frame of claim 1, wherein the package body comprises a thermoplastic resin or a thermosetting resin.

12. A semiconductor device package comprising:
a semiconductor device;
a package body having an internal space in which the semiconductor device is capable of being mounted;
a lead unit disposed so as to apply voltages to the semiconductor device and comprising internal leads embedded in the package body and having an area in which the semiconductor device is to be mounted, and external leads each being connected to the internal leads, respectively, each protruding from the package body and each having a contact portion that contacts a printed circuit board (PCB); and
a support structure disposed on external sides of the package body and supporting the external leads.

13. The semiconductor device package of claim 12, wherein the external sides of the package body comprise:
a left side;
a right side that faces the left side;
a front side that connects the left side and the right side;
a rear side that faces the front side; and
a bottom side that connects the left side and the right side and connects the front side and the rear side, and
the lead unit comprises a first lead unit and a second lead unit, and
the first lead unit comprises a first internal lead and a first external lead,
the second lead unit comprises a second internal lead and a second external lead, and
the first external lead and the second external lead are bent along the external sides of the package body, and
the first external lead protrudes from the left side, is bent, reaches an end of the left side in which the left side joins the bottom side, and is bent from the end of the left side to extend away from the left side, and
the second external lead protrudes from the right side, is bent, reaches an end of the right side in which the right side joins the bottom side, and is bent from the end of the right side to extend away from the right side.

14. The semiconductor device package of claim 13, wherein the support structure comprises:
a first stopper that protrudes from the front side and is disposed between a surface on which the bottom side extends, and the first external lead; and
a second stopper that protrudes from the front side and is disposed between the surface on which the bottom side extends, and the second external lead.

15. The semiconductor device package of claim 14, wherein the semiconductor device comprises a light emitting device.

16. A lead frame comprising:
a package body having an internal space configured to mount a semiconductor device;
a lead unit configured to apply voltages to the semiconductor device and comprising internal leads embedded in the package body and having an area in which the semiconductor device is to be mounted, and external leads each being connected to the internal leads respectively, protruding from the package body, and having a contact portion that contacts a printed circuit board (PCB); and
a support structure integrally disposed on external sides of the package body and comprising edge portions directly adjacent and in contact with a side portion of the external leads.

17. The lead frame of claim 16, wherein the lead unit comprises a first lead unit and a second lead unit, and
the first lead unit comprises a first internal lead and a first external lead,
the second lead unit comprises a second internal lead and a second external lead, and
the first external lead and the second external lead are bent along the external sides of the package body.

18. The lead frame of claim 17, wherein the support structure comprises:
a first stopper that protrudes from a bottom side of the package body and is disposed between a surface on which a rear side of the package body extends, and the first external lead; and
a second stopper that protrudes from the bottom side and is disposed between the surface on which the rear side extends, and the second external lead.

19. The lead frame of claim 1, wherein the support structure is not more protruding than the contact portion of each of the external leads.

20. The lead frame of claim 1, wherein the package body comprises a thermoplastic resin or a thermosetting resin.
